(19) United States
(12) Patent Application Publication
(10) Pub. No.: US 2019/0013370 A1
(43) Pub. Date: Jan. 10, 2019

(54) WOLED DISPLAY PANEL AND DISPLAY DEVICE

(71) Applicant: Shenzhen China Star Optoelectronics Semiconductor Display Technology Co., Ltd., Shenzhen, Guangdong (CN)

(72) Inventor: Chenglei Nie, Shenzhen (CN)

(21) Appl. No.: 15/741,170

(22) PCT Filed: Oct. 24, 2017
(86) PCT No.: PCT/CN2017/107495

§ 371 Date: Dec. 29, 2017

(30) Foreign Application Priority Data
Jul. 7, 2017 (CN) 201710553104.9

(51) Int. Cl. H01L 27/32

(52) U.S. Cl. CPC H01L 27/3246; H01L 51/5044; H01L 27/322; H01L 27/3213

(57) ABSTRACT

The present disclosure discloses a white organic light emitting diode (WOLED) display panel, which comprises a thin film transistor (TFT) array substrate and a color filter layer and a light emitting structure layer sequentially disposed on the TFT array substrate, wherein the light emitting structure layer comprises an anode layer, a pixel defining layer, a white organic light emitting layer and a cathode layer that are sequentially disposed, wherein the pixel defining layer comprises pixel opening portions and pixel spacing portions for spacing adjacent two of the pixel opening portions, and wherein a protruding insulating post spacer is disposed on each of the pixel spacing portions, and a protruding bend portion is formed in a part of the white organic light emitting layer corresponding to and covering the post spacer. The present disclosure also discloses a display device comprising the WOLED display panel as above.

### TECHNICAL FIELD

The present disclosure relates to a technical filed of a display, and more especially, to a WOLED (white organic light emitting diode) display panel and a display device.

### BACKGROUND ART

An organic light emitting diode (OLED) has a self-luminous characteristic and uses a thin coating of an organic material and a glass substrate, such that the organic material emits light when a current flows therethrough. Since an organic light emitting diode display screen has a wide viewing angle, and is able to save electric energy significantly, the organic light emitting diode is increasingly widely applied.

The core component of an OLED display device is an OLED display panel. The OLED display panel usually has such a structure that includes a thin film transistor (TFT) array substrate, and an anode layer, a pixel defining layer, a first common layer for transporting holes, a light emitting layer, a second common layer for transporting electrons and a cathode layer which are sequentially formed on the TFT array substrate. The OLED display panel uses such an operation principle that when an electric filed is applied between the anode layer and the cathode layer, the holes and electrons are transported to the light emitting layer through the first common layer and the second common layer, respectively, and recombine in the light emitting layer to emit light.

In order to achieve full color of the OLED display device, one way is to overlap a white organic light emitting diode (WOLED) and a color filter (CF) layer. Since the overlapped structure of the WOLED and CF layer does not require an accurate mask process and may realize a high resolution of the OLED display device, the one way is relatively widely used. In a WOLED display panel, a light emitting layer generally includes a blue sub-emissive layer, a green sub-emissive layer and a red sub-emissive layer, and intermediate layers with a good characteristic of transporting electrons and holes may be further disposed between adjacent two of the sub-emissive layers.

With an improvement of the resolution of a display panel, the number of pixel units in a unit area is increasing, so that a spacing distance between sub-pixels is decreasing. Further, for improving a display efficiency, many excellent transport materials are introduced into each of function layers for transporting holes and electrons such as the first common layer, the second common layer, the intermediate layer and the like. In the case of a spacing distance between sub-pixels being decreased and a transmission characteristic of the function layers being increased, a transverse current of the display panel also increases, causing crosstalk. That is to say, when one of the sub-pixels (i.e., a target sub-pixel) is lighted, a few holes may be injected into an adjacent sub-pixel by a transmission function layer, and recombine with electrons in the adjacent sub-pixel to emit light, which results in that light emitted by the target sub-pixel is impure, and this luminescence phenomenon is referred to leakage luminescence. Such leakage luminescence is especially apparent in a full colored WOLED display panel, thereby reducing a display quality of the WOLED display panel.

### SUMMARY

In consideration of the above disadvantages of the related art, the present disclosure provides a white organic light emitting diode (WOLED) display panel, which may effectively reduce a leakage luminescence between adjacent two of sub-pixels, and improve a display quality of the display panel.

For the above purpose, the present disclosure applies a technical solution as follows.

A WOLED display panel may include a thin film transistor (TFT) array substrate and a color filter layer and a light emitting structure layer sequentially disposed on the TFT array substrate, wherein the light emitting structure layer includes an anode layer, a pixel defining layer, a white organic light emitting layer and a cathode layer that are sequentially disposed, the pixel defining layer includes pixel opening portions and pixel spacing portions for spacing adjacent two of the pixel opening portions, a protruding insulating post spacer is disposed on each of the pixel spacing portions, and a protruding bend portion is formed in a part of the white organic light emitting layer corresponding to and covering the post spacer.

The post spacer may have a trapezoid-shape cross-section, and have an angle not less than 60° between a side surface and a bottom surface of the post spacer.

The post spacer has a rectangle-shaped or an inverted trapezoid-shaped cross-section.

Each of the pixel opening portions has a length H1, each of the post spacers has a length H2, and wherein H1≤H2.

A top of each of the pixel spacing portions has a width D1, each of the post spacers has a width D2, and wherein

$$\frac{1}{2} D 1 \leq D 2 \leq D 1.$$

The white organic light emitting layer includes a first common layer for transporting holes, a blue emissive layer, a green emissive layer, a red emissive layer and a second common layer for transporting electrons that are sequentially disposed.

An intermediate layer is further disposed between the blue emissive layer and the green emissive layer, and has a function of transporting electrons and holes.

A red sub-pixel, a green sub-pixel, a blue sub-pixel and a white sub-pixel are disposed in the light emitting structure layer. Each of the pixel opening portions corresponds to one of the sub-pixels. A red photoresist, a green photoresist, a blue photoresist and a transparent unit are disposed in the color filter layer corresponding to the red sub-pixel, the green sub-pixel, blue sub-pixel and white sub-pixel, respectively.

The anode layer includes a plurality of anodes, each of the anodes corresponding to one of the sub-pixels, and the cathode layer is integrally successive to cover all sub-pixels, such that the all sub-pixels commonly use the cathode layer.

The present disclosure also provides a display device including a driving unit and the WOLED display panel described as above supplied with a driving signal from the driving unit to display image.

Compared to the related art, embodiments of the present disclosure provides a WOLED display panel, in which a convex insulating post spacer is disposed between two adjacent sub-pixels, and a convex bend portion is formed in a part of an organic light emitting layer corresponding to and overlapping the post spacer, thereby increasing the transverse travel path of holes, reducing a leakage current between the two adjacent sub-pixels, effectively reducing a leakage luminescence between the two adjacent sub-pixels, and improving a display quality of the display panel.

### BRIEF DESCRIPTION OF THE DRAWINGS

FIG. 1 is a schematic structural view of a white organic light emitting diode (WOLED) display panel according to an embodiment of the present disclosure;

FIG. 2 is a schematic view of an arrangement structure of sub-pixels according to an embodiment of the present disclosure;

FIG. 3 is a schematic structural view of a white organic light emitting layer according to an embodiment of the present disclosure;

FIG. 4 is a schematic structural view of a post spacer according to another preferred embodiment of the present disclosure;

FIG. 5 is a schematic structural view of a post spacer according to still another preferred embodiment of the present disclosure; and

FIG. 6 is a schematic structural view of a display device according to an embodiment of the present disclosure.

### DETAILED DESCRIPTION OF EXEMPLARY EMBODIMENTS

In order for the purpose, technical solutions and advantages of the present disclosure to be more apparent, detailed description of exemplary embodiments of the present disclosure will be explained in detail below in conjunction with the accompanied drawings. Examples of the preferred implementations are illustrated in the drawings. The implementations of the present disclosure shown in the drawings and described according to the drawings are only exemplary, and the present disclosure is not limited to the implementations.

Here, it should be noted that the drawings only shows structures and/or process steps closely related to solutions according to the present disclosure, and other details that have little related to the present disclosure are omitted, in order to avoid obscuring the present disclosure due to unnecessary details.

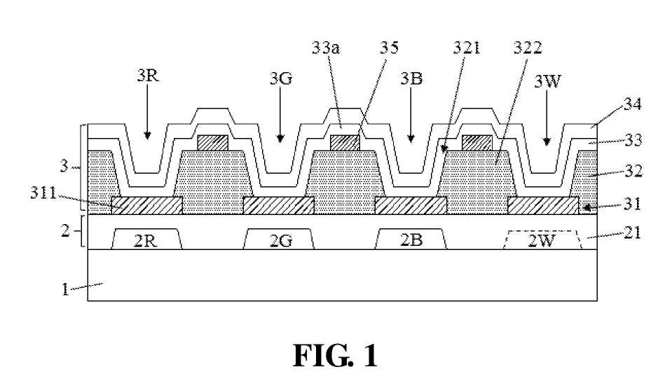

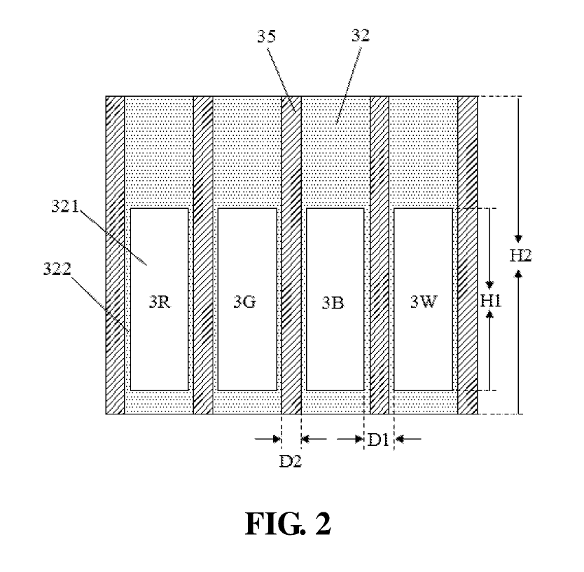

The present embodiment firstly provides a white organic light emitting (WOLED) display panel, and as show in FIGS. 1 and 2, the WOLED display panel includes a thin film transistor (TFT) array substrate and a color filter layer 2 and a light emitting structure layer 3 sequentially disposed on the TFT array substrate 1.

The light emitting structure layer 3 includes an anode layer 31, a pixel defining layer 32, a white organic light emitting layer 33 and a cathode layer 34 that are sequentially disposed. The pixel defining layer 32 includes pixel opening portions 321 and pixel spacing portions 322 for spacing adjacent two of the pixel opening portions 321. Particularly, a red sub-pixel 3R, a green sub-pixel 3G, a blue sub-pixel 3B and a white sub-pixel 3W are disposed in the light emitting structure layer 3, and each of the pixel opening portions 321 corresponds to one of the red sub-pixel 3R, the green sub-pixel 3G, the blue sub-pixel 3B and the white sub-pixel 3W.

In the color filter layer 2, a red photoresist 2R is disposed corresponding to the red sub-pixel 3R, a green photoresist 2G is disposed corresponding to the green sub-pixel 3G, a blue photoresist 2B is disposed corresponding to the blue sub-pixel 3B, and a transparent unit 2W is disposed corresponding to the white sub-pixel 3W. In the present embodiment, the color filter layer 2 further includes a flat layer 21 covering the red photoresist 2R, the green photoresist 2G, the blue photoresist 2B and the transparent unit 2W. The flat layer 21 is formed of a transparent organic material, and thus, the flat layer 21 can be completely filled into the transparent unit 2W, without using other transparent materials to fill a position corresponding to the transparent unit 2W.

As shown in FIG. 1, the anode layer 31 includes a plurality of anodes 311, each of which corresponds to one sub-pixel. That is, a bottom of each of the pixel opening portions 321 is disposed with one anode 311. The white light emitting layer 33 and the cathode layer 34 are integrally continuous to cover all of the sub-pixels, such that the white light emitting layer 33 and the cathode layer 34 are commonly used by all of the sub-pixels.

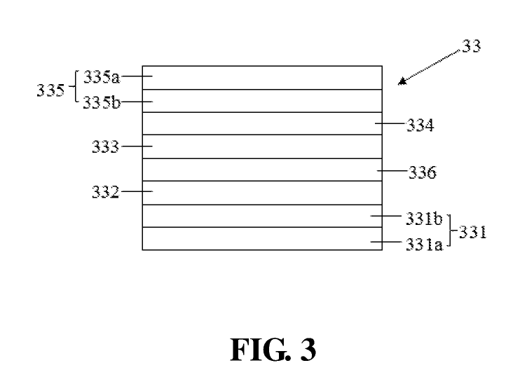

In the present embodiment, as shown in FIG. 3, the white organic light emitting layer 33 includes a first common layer 331 for transporting holes, a blue emissive layer (B-EML) 332, a green emissive layer (G-EML) 333, a red emissive layer (R-EML) 334 and a second common layer 335 for transporting electrons that are sequentially disposed on the anode layer 31. The first common layer 331 includes a hole injection layer (HIL) 331a and a hole transport layer (HTL) 331b sequentially disposed in a direction away from the anode layer 31, and may further include an electron barrier layer. The second common layer 335 includes an electron injection layer (EIL) 335a and an electron transport layer (ETL) 335b sequentially disposed in a direction away from the cathode layer 34, and may further include a hole barrier layer. Further, an intermediate layer 336 is disposed between the B-EML 332 and the G-EML 333, and has a function of transporting electrons and holes.

Referring to FIGS. 1 and 2, in the present embodiment, convex insulating post spacers (PSs) 35 are disposed above the pixel spacing portions 322 of the pixel defining layer 32, and convex bent portions 33a are formed in portions of the white organic light emitting layer 33 corresponding to and covering the PSs 35, thereby increasing a transverse transporting path of the holes, reducing a leakage current between adjacent two of the sub-pixels, effectively reducing a leakage luminescence between adjacent two of the sub-pixels, and improving the display quality of the display panel.

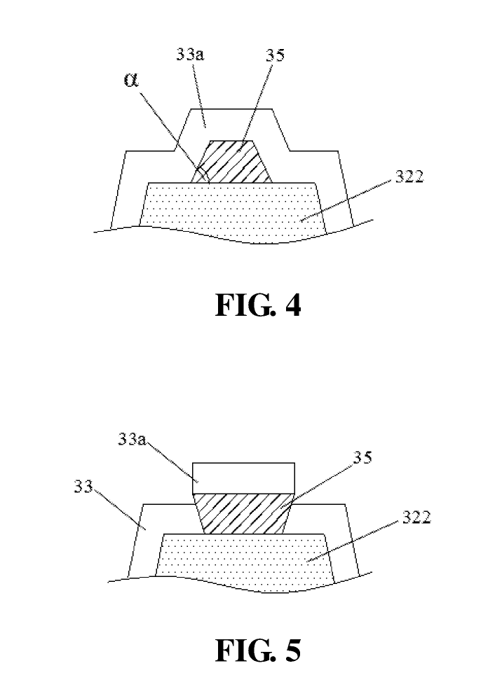

As shown in FIG. 1, in the present embodiment, the PS 35 has a cross-section having a rectangular shape, that is, an angle between a side surface and a bottom surface of the PS 35 is 90°. A part of the bent portion 33a of the white light emitting layer 33 corresponding to the side surface of the PS 35 has a smaller thickness, such that on-resistance thereof increases and the leakage current is accordingly reduced. In another embodiment, as shown in FIG. 4, the PS 35 on the pixel spacing portion 322 has a cross-section having a trapezoid shape. The steeper a slope (side surface) of the PS 35 is, the thinner the portion of the bent portion 33a corresponding to the slope is, such that the on-resistance of the transverse conduction path is greater, the leakage current is also smaller. Accordingly, when the PS 35 has a trapezoid-shaped cross-section, the angle α between the side surface and the bottom surface of the PS 35 is disposed to be not less than 60°. In the most preferred embodiment, as shown in FIG. 5, the PS 35 on the pixel spacing portion 322 is disposed to have an inverted trapezoid-shaped cross-section. At this time, a breakage may occur between the bent portion 33a of the white organic light emitting layer 33 and a body of the white organic light emitting layer 33, which may effectively prevent the leakage current from transverse transmitting, and eliminating the leakage issue.

A length of the PS 35 should be not less than a length of the pixel opening portion 321, and a width of the PS 35 is preferably not less than half a width of the pixel spacing portion 322. In particular, as shown in FIG. 2, the length of the pixel opening portion 321 is H1, the length of the PS 35 is H2, and H1≤H2 When the length H2 of the PS 35 is equal to the length H1 of the pixel opening portion 321, the transverse leakage current can be effectively reduced, and thus the length H2 is as long as possible. A width of a top of the pixel spacing portion 322 is D1, a width of the PS 35 is D2, and the widths D1 and D2 meet

$$\frac{1}{2} D 1 \leq D 2 \leq D 1 ,$$

preferably, the width D2 is disposed to be equal to the width D1. The width of the PS 35 is longer, the conduction path of the transverse leakage current is longer, and the leakage current is smaller.

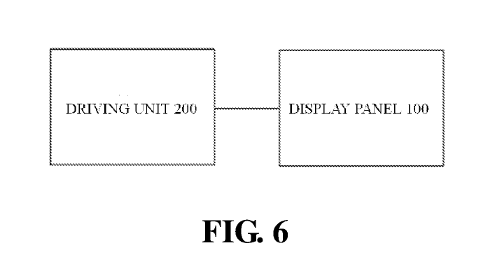

The present embodiment further provides a display device, and as shown in FIG. 6, the display device includes a driving unit 200 and a display panel 100. The driving unit 200 provides a driving signal to the display panel 100 to enable the display panel to display images. The display panel 100 applies the WOLED display panel as above mentioned in the present disclosure.

As above, the present disclosure provides a WOLED display panel, in which a convex insulating post spacer is disposed between two adjacent pixels, and a convex bent portion is formed in a portion of the organic light emitting layer corresponding to and covering the post spacer, so that the transverse travel path of holes is increased, the leakage current between the two adjacent pixels is reduced, the leakage phenomena is effectively reduced, and the display quality of the display panel is improved.

It is to be noted that, in this context, relationship terms such as “first” and “second” are used only to distinguish an entity or an operation from another entity or operation without necessarily requiring or implying the actual relationship or sequence between the entities or operations. Moreover, the terms such as “includes”, “including”, “comprise”, “comprising” or any other variant thereof are intended to encompass a non-exclusive inclusion, such that a process, method, article, or device including a series of elements not only includes those elements, but also includes other elements that are not explicitly listed or are inherent elements of such process, method, article, or equipment. In the absence of more restrictions, an element defined by the description of “including one of” do not preclude the presence of additional elements in the process, method, article, or device that includes the elements.

The above mentioned is just detailed implements of the present disclosure, and it should be noted that many amendments and modifications can be made in the present disclosure to those skilled in the art without departing from the principle of the present disclosure, and should be regarded as the scope of protection of the present disclosure.

What is claimed:

1. A white organic light emitting diode (WOLED) display panel, comprising:
a thin film transistor (TFT) array substrate; and
a color filter layer and a light emitting structure layer sequentially disposed on the TFT array substrate,
wherein the light emitting structure layer comprises an anode layer, a pixel defining layer, a white organic light emitting layer and a cathode layer that are sequentially disposed,
wherein the pixel defining layer comprises pixel opening portions and pixel spacing portions for spacing adjacent two of the pixel opening portions, and
wherein a protruding insulating post spacer is disposed on each of the pixel spacing portions, and a protruding bend portion is formed in a part of the white organic light emitting layer corresponding to and covering the post spacer.

2. The WOLED display panel of claim 1, wherein the post spacer has a trapezoid-shaped cross-section, and has an angle not less than 60° between a side surface and a bottom surface of the post spacer.

3. The WOLED display panel of claim 1, wherein the post spacer has a rectangle-shaped or an inverted trapezoid-shaped cross-section.

4. The WOLED display panel of claim 1, wherein each of the pixel opening portions has a length H1, and each of the post spacers has a length H2, and wherein H1 ≤H2.

5. The WOLED display panel of claim 1, wherein a top of each of the pixel spacing portions has a width D1, and each of the post spacers has a width D2, and wherein
$$\frac{1}{2} D 1 \leq D 2 \leq D 1.$$

6. The WOLED display panel of claim 1, wherein the white organic light emitting layer comprises a first common layer for transporting holes, a blue emissive layer, a green emissive layer, a red emissive layer and a second common layer for transporting electrons that are sequentially disposed.

7. The WOLED display panel of claim 6, wherein an intermediate layer is further disposed between the blue emissive layer and the green emissive layer, and has a function of transporting electrons and holes.

8. The WOLED display panel of claim 1, wherein a red sub-pixel, a green sub-pixel, a blue sub-pixel and a white sub-pixel are disposed in the light emitting structure layer,
wherein each of the pixel opening portions corresponds to one of the sub-pixels, and
wherein a red photoresist, a green photoresist, a blue photoresist and a transparent unit are disposed in the color filter layer corresponding to the red sub-pixel, the green sub-pixel, blue sub-pixel and white sub-pixel, respectively.

9. The WOLED display panel of claim 8, wherein the anode layer comprises a plurality of anodes, each of the anodes corresponding to one of the sub-pixels, and
wherein the cathode layer is integrally successive to cover all sub-pixels, and all of the sub-pixels commonly use the cathode layer.

10. A display device, comprising:
a driving unit; and
a white organic light emitting diode (WOLED) display panel supplied with a driving signal from the driving unit to display images,
wherein the WOLED display panel comprises:
a thin film transistor (TFT) array substrate; and
a color filter layer and a light emitting structure layer sequentially disposed on the TFT array substrate,
wherein the light emitting structure layer comprises an anode layer, a pixel defining layer, a white organic light emitting layer and a cathode layer that are sequentially disposed,
wherein the pixel defining layer comprises pixel opening portions and pixel spacing portions for spacing adjacent two of the pixel opening portions, and
wherein a protruding insulating post spacer is disposed on each of the pixel spacing portions, and a protruding bend portion is formed in a part of the white organic light emitting layer corresponding to and covering the post spacer.

11. The display device of claim 10, wherein the post spacer has a trapezoid-shaped cross-section, and has an angle not less than 60° between a side surface and a bottom surface of the post spacer.

12. The display device of claim 10, wherein the post spacer has a rectangle-shaped or an inverted trapezoid-shaped cross-section.

13. The display device of claim 10, wherein each of the pixel opening portions has a length H1, each of the post spacers has a length H2, and wherein H1≤H2.

14. The display device of claim 10, wherein a top of each of the pixel spacing portions has a width D1, each of the post spacers has a width D2, and wherein
$$\frac{1}{2} D 1 \leq D 2 \leq D 1.$$

15. The display device of claim 10, wherein the white organic light emitting layer comprises a first common layer for transporting holes, a blue emissive layer, a green emissive layer, a red emissive layer and a second common layer for transporting electrons that are sequentially disposed.

16. The display device of claim 15, wherein an intermediate layer is further disposed between the blue emissive layer and the green emissive layer, and has a function of transporting electrons and holes.

17. The display device of claim 10, wherein a red sub-pixel, a green sub-pixel, a blue sub-pixel and a white sub-pixel are disposed in the light emitting structure layer,
wherein each of the pixel opening portions corresponds to one of the sub-pixels, and
wherein a red photoresist, a green photoresist, a blue photoresist and a transparent unit are disposed in the color filter layer corresponding to the red sub-pixel, the green sub-pixel, blue sub-pixel and white sub-pixel, respectively.

18. The display device of claim 17, wherein the anode layer comprises a plurality of anodes, each of the anodes corresponding to one of the sub-pixels, and
wherein the cathode layer is integrally successive to cover all sub-pixels, such that the all sub-pixels commonly use the cathode layer.
